(19) United States
(12) Patent Application Publication
(10) Pub. No.: US 2021/0002765 A1
(43) Pub. Date: Jan. 7, 2021

(54) THERMAL ALD OF METAL OXIDE USING ISSG

(71) Applicant: Applied Materials, Inc., Santa Clara, CA (US)

(72) Inventor: Tatsuya E. Sato, San Jose, CA (US)

(73) Assignee: Applied Materials, Inc., Santa Clara, CA (US)

(21) Appl. No.: 16/922,528

(22) Filed: Jul. 7, 2020

Related U.S. Application Data
(60) Provisional application No. 62/871,199, filed on Jul. 7, 2019.

(51) Int. Cl. C23C 16/455; C23C 16/02; H01L 21/02; C23C 16/40

(52) U.S. Cl. CPC C23C 16/45536; C23C 16/403; H01L 21/02178; C23C 16/02

(57) ABSTRACT

A method of forming a metal oxide is disclosed herein. The methods are performed by atomic layer deposition without the use of plasma. The methods utilize a heated substrate exposed to a co-flow of H₂ and O₂ to form radical species which react with metal precursors to form metal oxides.

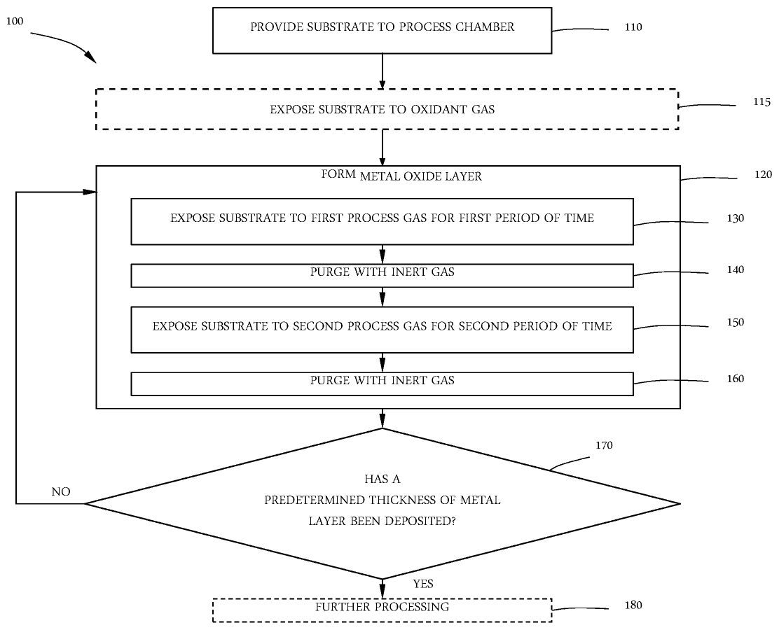

### CROSS-REFERENCE TO RELATED APPLICATIONS

This application claims priority to U.S. Provisional Application No. 62/871,199, filed Jul. 7, 2019, the entire disclosure of which is hereby incorporated by reference herein.

### TECHNICAL FIELD

Embodiments of the present disclosure generally relate to methods for forming metal oxides using in-situ steam generation (ISSG). More specifically, some embodiments of the disclosure relate to methods for forming metal oxides using radicals generated at the substrate surface.

### BACKGROUND

Metal oxide films are used throughout the semiconductor industry. One example is in the use of ALO films as blocking layers in 3DNAND devices. Given the large surface areas and deep device features found in many 3DNAND devices, thermal atomic layer deposition is often utilized to deposit metal oxide films in these applications.

Thermal atomic layer deposition (ALD) processes for metal oxides typically utilize H₂O, H₂O₂, O₃ or alcohols as oxidizers. Of these oxidizers, H₂O₂, O₃ and many alcohols are unsuitable for use at higher temperatures. At higher temperatures, these species lose oxidative potential due to decomposition and recombination.

Water, especially when introduced into a processing chamber as water vapor or steam, is difficult to purge from the processing chamber. Accordingly, when used in ALD processes, water is often still present in the chamber when a subsequent reactant is introduced, resulting in a parasitic CVD reaction.

Accordingly, there is a need for new methods of thermal ALD for depositing metal oxides.

### SUMMARY

One or more embodiments of the disclosure are directed to a method of forming a semiconductor device. The method comprises performing one or more cycles of an atomic layer deposition (ALD) cycle. The ALD cycle comprises exposing a substrate surface to a metal precursor to form a metal species on the substrate surface and generating a radical species at the substrate surface to convert the metal species to a metal oxide.

Additional embodiments of the disclosure are directed to a method of forming a metal oxide. The method comprises performing a plurality of cycles of an atomic layer deposition (ALD) cycle. Each ALD cycle comprises exposing a substrate surface to a metal precursor to form a metal species on the substrate surface, and generating a radical species within 5 nm of the substrate surface to convert the metal species to a metal oxide. The substrate surface is maintained at a temperature greater than or equal to about 500° C.

Further embodiments of the disclosure are directed to a non-transitory computer readable medium including instructions, that, when executed by a controller of a processing chamber, cause the processing chamber to perform operations of: flowing a metal precursor; flowing H₂ and an oxidant; and maintaining an elevated temperature of a substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The FIGURE illustrates an exemplary process sequence for the formation of a metal oxide according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed separately to the two or more reactive compounds which are introduced into a reaction zone of a processing chamber.

In a time-domain ALD process, exposure to each reactive compound is separated by a time delay to allow each compound to adhere and/or react on the substrate surface and then be purged from the processing chamber. These reactive compounds are said to be exposed to the substrate sequentially.

In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., metal precursor gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used in this specification and the appended claims, the terms “precursor”, “reactant”, “reactive gas” and the like are used interchangeably to refer to any gaseous species that can react with the substrate surface.

Some embodiments of the disclosure are directed to processes that use a reaction chamber with multiple gas ports that can be used for introduction of different chemicals or plasma gases. Spatially, these gas ports (also referred to as channels) are separated by inert purging gases and/or vacuum pumping holes to create a gas curtain that minimizes or eliminates mixing of gases from different gas ports to avoid unwanted gas phase reactions. Wafers moving through these different spatially separated ports get sequential and multiple surface exposures to different chemical or plasma environment so that layer by layer film growth in spatial ALD mode or surface etching process occur. In some embodiments, the processing chamber has modular architectures on gas distribution components and each modular component has independent parameter control (e.g., RF or gas flow) to provide flexibility to control, for example, gas flow and/or RF exposure.

Embodiments of the present disclosure relate to methods for depositing or forming a metal oxide. Embodiments of the present disclosure are performed by atomic layer deposition (ALD). Embodiments of the present disclosure are performed by thermal ALD.

Some embodiments of the disclosure advantageously provide metal oxides with improved (e.g., reduced) nucleation delays. Some embodiments of the disclosure advantageously provide metal oxides with improved film properties. In some embodiments, these film properties are selected from one or more of higher film density, lower leakage, higher V_{bd}, higher k value, and/or less shrinkage after crystallization. Some embodiments of the disclosure advantageously provide metal oxides with low film impurities (e.g, —H, —OH bonds). Some embodiments of the disclosure advantageously provide methods with reduced parasitic CVD reactions and/or better chamber productivity/stability. Some embodiments of the disclosure advantageously provide improved film step coverage. Some embodiments of the disclosure advantageously provide methods for in-situ SiN to SiO oxidation/conversion before the metal oxide deposition.

The FIGURE depicts a generalized method for forming a metal film on a substrate in accordance with one or more embodiment of the disclosure. The method 100 generally begins at 110, where a substrate upon which a metal oxide film is to be formed is provided and placed into a processing chamber. As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the metal oxide film, for example, by polishing, etching, reduction, oxidation, halogenation, hydroxylation, annealing, baking, or the like.

At 120, a metal oxide film is formed on the substrate surface. The metal film may be formed via a cyclical deposition process, such as atomic layer deposition (ALD), or the like. In some embodiments, the forming of a metal oxide film via a cyclical deposition process may generally comprise exposing the substrate to two or more process gases separately. In time-domain ALD embodiments, exposure to each of the process gases are separated by a time delay/pause to allow the components of the process gases to adhere and/or react on the substrate surface.

Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases.

In spatial ALD embodiments, exposure to each of the process gases occurs simultaneously to different parts of the substrate so that one part of the substrate is exposed to the first reactive gas while a different part of the substrate is exposed to the second reactive gas (if only two reactive gases are used). The substrate is moved relative to the gas delivery system so that each point on the substrate is sequentially exposed to both the first and second reactive gases. In any embodiment of a time-domain ALD or spatial ALD process, the sequence may be repeated until a predetermined layer thickness is formed on the substrate surface.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The process of forming the metal oxide film at 120 may begin by exposing the substrate to a first reactive gas. The first reactive gas comprises a metal precursor and is exposed to the substrate for a first period of time, as shown at 130.

The metal precursor may be any suitable precursor to form a metal species on the substrate surface. In some embodiments, the metal precursor comprises a metal center and one or more ligands. In some embodiments, the metal center comprises one or more metal atoms. Stated differently, in some embodiments, the metal precursor is one or more of a dimer, trimer or tetramer.

The metal of the metal precursor will become the metal of the metal oxide film. In some embodiments, the metal precursor comprises aluminum. In these embodiments, the metal oxide comprise aluminum oxide. In some embodiments, the metal precursor comprises trimethyl aluminum (TMA). In some embodiments, the metal precursor comprises or consists essentially of aluminum chloride (AlCl₃).

The metal precursor is delivered to the processing chamber as a metal precursor containing gas. The metal precursor containing gas may further comprise a carrier gas to effectively transport the metal precursor to the processing chamber. The metal precursor containing gas may be provided in one or more pulses or continuously. The flow rate of the metal precursor containing gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The metal precursor containing gas can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to the metal precursor containing gas may be any suitable amount of time necessary to allow the metal precursor to form an adequate adsorption layer atop the substrate surface(s). For example, the process gas may be flowed into the process chamber for a period of about 0.1 seconds to about 90 seconds. In some time-domain ALD processes, the metal precursor containing gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as the metal precursor containing gas. In some embodiments, the inert gas may be the same, or alternatively, may be different from the carrier gas provided to the process chamber with the metal precursor containing gas. The inert gas may be mixed with the metal precursor containing gas (e.g., as a diluent gas) or be provided separately and can be pulsed or of a constant flow. In some embodiments, the inert gas is flowed into the processing chamber at a constant flow in the range of about 1 to about 10000 sccm. The inert gas may be any inert gas, for example, such as nitrogen, argon, helium, neon, or combinations thereof.

In addition to the foregoing, additional process parameters may be regulated while exposing the substrate to the metal precursor containing gas. For example, in some embodiments, the process chamber may be maintained at a pressure of about 0.2 to about 100 Torr, or in the range of about 0.3 to about 90 Torr, or in the range of about 0.5 to about 80 Torr, or in the range of about 1 to about 50 Torr.

Next, at 140, the process chamber (especially in time-domain ALD) may be purged using an inert gas. (This may not be needed in spatial ALD processes as there are gas curtains separating the reactive gases.) The inert gas may be any inert gas, for example, such as nitrogen, argon, helium, neon, or the like. In some embodiments, the inert gas may be the same, or alternatively, may be different from the inert/carrier gas provided to the process chamber during the exposure of the substrate to the metal precursor containing gas at 130. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of about 0 to about 10000 sccm to purge the process chamber. In spatial ALD, purge gas curtains are maintained between the flows of reactive gases and purging the process chamber may not be necessary. In some embodiments of a spatial ALD process, the process chamber or region of the process chamber may be purged with an inert gas.

The flow of inert gas may facilitate removing any excess first process gas components and/or excess reaction byproducts from the process chamber to prevent unwanted gas phase reactions of the first and second process gases.

Next, at 150, the substrate is exposed to a second process gas for a second period of time. The second process gas is used to generate a radical species at the substrate surface. The radical species convert the metal species to a metal oxide. The second reactive gas may also be referred to as the oxidant gas.

The oxidant gas may be any suitable gas to generate a radical species at the substrate surface and convert the metal species to a metal oxide. In some embodiments, the oxidant gas comprises a co-flow of H₂ and an oxidant. In some embodiments, the oxidant comprises O₂ or N₂O. In some embodiments, the oxidant consists essentially of O₂. As used in this regard, an oxidant which “consists essentially of” O₂ means that the oxidant gas comprises greater than 95%, 98%, 99% or 99.5% of O₂ on a molar basis as a percentage of total oxidizing species (e.g., excluding H₂ and any inert gas). In some embodiments, the radical species generated comprise one or more of O* and OH*.

In some embodiments, the oxidant comprises substantially no water. Without being bound by theory, it is believed that the use of water as an oxidant in ALD oxidation reactions often leads to parasitic CVD reactions due to the presence of water in the chamber even after a chamber purge. These CVD reactions reduce the amount of metal precursor available for reaction as well as contaminate the chamber or the substrates in process. In some embodiments, substantially no parasitic CVD of metal oxide is observed.

In some embodiments, the oxidant gas may be supplied in its component parts. For example, in some embodiments, a H₂ gas is flowed into the chamber followed by an oxidant gas flow. In some embodiments, these gas flows overlap, resulting in a co-flow. In some embodiments, the chamber is purged with H₂ gas and an oxidant gas or oxidant is pulsed into the chamber after the H₂ purge.

In some embodiments, the ratio of H₂ and oxidant in the co-flow may be controlled. In some embodiments, the flow ratio of H₂:oxidant is less than or equal to about 1:2, less than or equal to about 1:5, less than or equal to about 1:10, less than or equal to about 1:20, less than or equal to about 1:50, or less than or equal to about 1:100. In some embodiments, the flow percentage of H₂ is less than or equal to about 50%, less than or equal to about 25%, less than or equal to about 10%, less than or equal to about 5%, less than or equal to about 1%, less than or equal to about 0.5%, or less than or equal to about 0.1%.

Additional process parameters may be regulated while exposing the substrate to the oxidant gas. For example, in some embodiments, the process chamber may be maintained at a pressure of about 0.2 to about 100 Torr, or in the range of about 0.3 to about 90 Torr, or in the range of about 0.5 to about 80 Torr, or in the range of about 1 to about 50 Torr.

The oxidant gas may be provided in one or more pulses or continuously. The flow rate of the oxidant gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The oxidant gas can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to the oxidant gas may be any suitable amount of time necessary to generate sufficient radical species to react with the adsorbed metal species on the substrate surface. For example, the process gas may be flowed into the process chamber for a period of about 0.1 seconds to about 90 seconds. In some time-domain ALD processes, the metal precursor gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as the oxidant gas. The inert gas may be mixed with the oxidant gas (e.g., as a diluent gas) or be provided separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, or combinations thereof.

Next, at 160, the process chamber may be purged using an inert gas. The inert gas may be any inert gas, for example, such as nitrogen, argon, helium, neon, or the like. In some embodiments, the inert gas may be the same, or alternatively, may be different from the inert gas provided to the process chamber during previous process routines. In embodiments where the inert gas is the same, the purge may be performed by diverting the second process gas from the process chamber, allowing the inert gas to flow through the process chamber, purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of greater than 0 to about 10,000 sccm to purge the process chamber.

While the generic embodiment of the processing method shown in the FIGURE includes only two pulses of reactive gases, it will be understood that this is merely exemplary and that additional pulses of reactive gases may be used.

The sub processes of 120 comprise a cycle. A cycle may be performed in any order as long as the reactive gases are separated by a purge of the processing chamber. In some embodiments, one or more cycles are performed. In some embodiments, a plurality of cycles (e.g., more than one) is performed.

The deposition/formation process is performed as a thermal process without the use of plasma reactants. Stated differently, in some embodiments, the method is performed without plasma. Stated differently, in some embodiments, no plasma is generated.

Next, at 170, it is determined whether the metal oxide film has achieved a predetermined thickness. If the predetermined thickness has not been achieved, the method 100 returns to 120 to continue forming the metal oxide until the predetermined thickness is reached. Once the predetermined thickness has been reached, the method 100 can either end or proceed to 180 for optional further processing (e.g., bulk deposition of another film).

The temperature of the substrate during deposition can be controlled, for example, by setting the temperature of the substrate support or susceptor. In some embodiments, the substrate surface is maintained at a temperature greater than or equal to about 500° C., greater than or equal to about 550° C., greater than or equal to about 600° C., greater than or equal to about 650° C., or greater than or equal to about 700° C. In some embodiments, the substrate surface is maintained at a temperature in a range of about 500° C. to about 1000° C., about 500° C. to about 800° C., about 500° C. to about 750° C., about 500° C. to about 700° C., about 500° C. to about 650° C., or about 500° C. to about 600° C.

The temperature of the substrate surface is elevated during deposition in order to form the radical species. Stated differently, in some embodiments, the radical species are generated due to the elevated surface temperature of the substrate surface. At the deposition temperature, H₂ and the oxidant form the radical species.

In some embodiments, the radical species are generated “at the substrate surface”. As used in this regard, radicals generated at the substrate surface are generated within 30 nm, within 20 nm, within 10 nm, within 5 nm, within 2 nm, within 1 nm of the substrate surface. In some embodiments, radicals generated “at the substrate surface” are generated on the substrate surface.

In some embodiments, the metal oxide has low impurity levels. In some embodiments, the metal oxide has low levels of H and OH ligands. In some embodiments, the metal oxide has low levels of —H and —OH bonds. In some embodiments, the low level of —H and —OH bonds are evaluated relative to other methods of forming metal oxides (e.g., plasma processes, water-based processes, CVD processes). In some embodiments, the level of —H and —OH bonds is less than or equal to about 5%, less than or equal to about 2%, less than or equal to about 1%, less than or equal to about 0.5%, or less than or equal to about 0.1% of the total bond count within the metal oxide.

The method 100 described above with respect to the FIGURE can generally be described as an AB cycle, with A corresponding to the metal precursor and B corresponding to the oxidant gas used to generate the radical species. In some embodiments, the method may further comprise a B-type pulse before the cycle begins. Stated differently, in some embodiments, the method 100 comprises generating a radical species at the substrate surface to oxidize the substrate surface before performing one or more cycles of an atomic layer deposition (ALD) cycle.

As shown at 115, in some embodiments, the substrate is exposed to the oxidant gas to generate the radical species. This process step may alter the substrate surface before the deposition/formation of the metal oxide. In some embodiments, a silicon nitride surface is oxidized to form a silicon oxide surface. In some embodiments, a silicon surface is oxidized to form a silicon oxide surface.

The depth of oxidation may be controlled. In some embodiments, the surface is oxidized to a depth greater than or equal to about 5 Å, greater than or equal to about 10 Å, greater than or equal to about 15 Å, greater than or equal to about 20 Å, greater than or equal to about 25 Å, or greater than or equal to about 30 Å.

Some embodiments of the disclosure relate to a general processing chamber for performing the disclosed methods. In some embodiments, the processing chamber includes at least one controller coupled to one or more of the processing chamber, substrate support, thermostat, flow controller, pressure gauge, pump, feedback circuit, reaction space pressure gauge or gas distribution assembly. In some embodiments, there are more than one controller connected to the individual components and a primary control processor is coupled to each of the separate controller or processors to control the system. The controller may be one of any form of general-purpose computer processor, microcontroller, microprocessor, etc., that can be used in an industrial setting for controlling various chambers and sub-processors.

The at least one controller can have a processor, a memory coupled to the processor, input/output devices coupled to the processor, and support circuits to communicate between the different electronic components. The memory can include one or more of transitory memory (e.g., random access memory) and non-transitory memory (e.g., storage).

The memory, or computer-readable medium, of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the processing chamber. The support circuits are coupled to the processor for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller has one or more configurations to execute individual processes or sub-processes to perform the method. The controller can be connected to and configured to operate intermediate components to perform the functions of the methods. For example, the controller can be connected to and configured to control one or more of gas valves, actuators, motors, heaters, vacuum control, etc.

The controller or non-transitory computer readable medium of some embodiments has one or more configurations selected from: a configuration to move a substrate on the robot between the plurality of processing chambers and metrology station; a configuration to load and/or unload substrates from the system; a configuration to flow a metal precursor into the processing chamber; a configuration to purge the processing chamber; a configuration to flow the oxidant gas into the processing chamber; and/or a configuration to maintain the temperature of the substrate.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
performing one or more cycles of an atomic layer deposition (ALD) cycle, the ALD cycle comprising exposing a substrate surface to a metal precursor to form a metal species on the substrate surface and generating a radical species at the substrate surface to convert the metal species to a metal oxide.

2. The method of claim 1, wherein the substrate surface is maintained at a temperature greater than or equal to about 500° C.

3. The method of claim 1, wherein the radical species generated from an oxidant gas comprising a co-flow of H₂ and an oxidant.

4. The method of claim 3, wherein the oxidant comprises O₂ or N₂O.

5. The method of claim 4, wherein the oxidant consists essentially of O₂.

6. The method of claim 3, wherein the co-flow comprises a continuous flow of hydrogen (H₂) with an oxidant pulse.

7. The method of claim 1, wherein the radical species are generated within 5 nm of the substrate surface.

8. The method of claim 1, wherein substantially no parasitic CVD of metal oxide is observed.

9. The method of claim 1, wherein the metal precursor comprises aluminum.

10. The method of claim 9, wherein the metal precursor comprises aluminum chloride (AlCl₃).

11. The method of claim 1, wherein the metal oxide has low levels of —H and —OH bonds.

12. The method of claim 1, wherein more than one cycle is performed.

13. The method of claim 1, further comprising generating a radical species at the substrate surface to oxidize the substrate surface before performing one or more cycles of an atomic layer deposition (ALD) cycle.

14. The method of claim 1, wherein the radical species are generated due to an elevated surface temperature of the substrate surface.

15. The method of claim 1, wherein no plasma is generated.

16. A method of forming a metal oxide, the method comprising:
performing a plurality of cycles of an atomic layer deposition (ALD) cycle, each ALD cycle comprising:
exposing a substrate surface to a metal precursor to form a metal species on the substrate surface; and
generating a radical species within 5 nm of the substrate surface to convert the metal species to a metal oxide, the substrate surface maintained at a temperature greater than or equal to about 500° C.

17. The method of claim 16, wherein generating the radical species at the substrate surface comprises co-flowing H₂ and O₂.

18. The method of claim 16, wherein the metal precursor comprises aluminum chloride (AlCl₃).

19. The method of claim 16, further comprising generating a radical species at the substrate surface to oxidize the substrate surface before performing the plurality of cycles of an atomic layer deposition (ALD) cycle.

20. A non-transitory computer readable medium including instructions, that, when executed by a controller of a processing chamber, cause the processing chamber to perform operations of:
flowing a metal precursor;
flowing H₂;
flowing an oxidant; and
maintaining an elevated temperature of a substrate.
